(19) United States
(12) Patent Application Publication
(10) Pub. No.: US 2014/0138837 A1
(43) Pub. Date: May 22, 2014

(54) SANDWICHED DIFFUSION BARRIER AND METAL LINER FOR AN INTERCONNECT STRUCTURE

(71) Applicants: STMICROELECTRONICS, INC., Coppell, TX (US); INTERNATIONAL BUSINESS MACHINES CORPORATION, Armonk, NY (US); GLOBALFOUNDRIES INC, Grand Cayman (KY)

(72) Inventors: Chengyu Niu, Fishkill, NY (US); Andrew Simon, Fishkill, NY (US); Tibor Bolom, Wappingers Falls, NY (US)

(73) Assignees: STMicroelectronics, Inc., Coppell, TX (US); GlobalFoundries Inc, Grand Cayman (KY); International Business Machines Corporation, Armonk, NY (US)

(21) Appl. No.: 13/682,326

(22) Filed: Nov. 20, 2012

(51) Int. Cl. H01L 21/768; H01L 23/485

(52) U.S. Cl. CPC H01L 21/76846; H01L 23/485
USPC 257/773; 438/653

(57) ABSTRACT

A trench is opened in a dielectric layer. The trench is then lined with a sandwiched diffusion barrier and metal liner structure and a metal seed layer. The sandwiched diffusion barrier and metal liner structure includes a conformal metal liner layer sandwiched between a first diffusion barrier layer and a second diffusion barrier layer. The metal seed layer is at least lightly doped. The lined trench is then filled by electroplating with a metal fill material. A dielectric cap layer is then deposited over the metal filled trench. Dopant from the doped metal seed layer is then migrated to an interface between the metal filled trench and the dielectric cap layer to form a self-aligned metal cap.

### TECHNICAL FIELD

The present invention relates to a method for manufacturing integrated circuits and, in particular, to a method of manufacturing a diffusion barrier and metal liner for an interconnect structure of an integrated circuit.

### BACKGROUND

The damascene and dual damascene processes for forming interconnect structures such as metal lines, vias and other interconnects in integrated circuits are well known to those skilled in the art. These processes typically require the formation of a diffusion barrier and metal liner over a wafer surface (including on the side walls and floor of any trench structures produced at locations where metal interconnect structures are desired). The diffusion barrier layer provides a block to undesired migrations and the metal liner provides an adhesion layer. Next, a metal seed layer is deposited over the diffusion barrier and metal liner in order to provide a low-resistance electrical path which supports a subsequent uniform metal electroplating over the wafer surface to be accomplished. The metal electroplating process fills the lined trench structures and defines the resulting interconnect structures of a metallization layer for the integrated circuit.

Reference is now made to FIGS. 1A-1I (not drawn to scale) which illustrate process steps for forming a metal interconnect structure of an integrated circuit in accordance with the prior art. The known damascene process may generally be described as follows: As shown in FIG. 1A, a wafer 10 is formed which comprises a semiconductor substrate 12 including integrated circuit devices formed in and/or on the substrate (not shown), a pre-metal dielectric (PMD) layer 14 overlying the substrate, and a plurality of electrical contact members 16, such as tungsten plugs or the like, extending through the PMD layer to reach the integrated circuit devices. The pre-metal dielectric (PMD) layer 14 is planarized using, for example, chemical mechanical polishing (CMP) to provide a flat surface for supporting metallization layers of the integrated circuit device.

Next, a low-k intermetal dielectric layer 18 is provided over the PMD layer 14 (FIG. 1B), the dielectric layer 18 for example being formed of a multilayer structure including a low-k layer and one or more mask layers (for example including a TEOS hard mask and titanium nitride hard mask). This multilayer low-k intermetal dielectric layer 18 is also planarized. A trench 20 is then formed extending into and perhaps through the multiple layers of the low-k intermetal dielectric layer 18 (FIG. 1C). The trench 20 is provided at a location where an interconnect structure is to be located, and in a preferred implementation will have a depth sufficient to expose the top surface of the underlying electrical contact member 16.

A blanket formation of a diffusion barrier layer 22 is then made (FIG. 1D) on the wafer (including over the top of the low-k intermetal dielectric layer 18 and on the side walls and floor within the trench 20). This diffusion barrier layer 22 serves to block the migration of subsequently deposited metal atoms for the interconnect structure into the low-k intermetal dielectric layer, as well as block the diffusion in the opposite direction of contaminants from the low-k intermetal dielectric layer to the interconnect structure. The diffusion barrier layer 22 is typically made of tantalum nitride.

Next, a metal liner layer 23 is deposited over the diffusion barrier layer 22 (FIG. 1E). The metal liner layer 23 functions as an adhesion layer that assists in increasing the adhesion of subsequently deposited layers. The metal liner layer 23 is typically made of tantalum, cobalt or ruthenium.

A metal seed layer 24 is then formed on the wafer (FIG. 1F) using any suitable deposition process such as sputtering over the metal liner layer 23. This seed layer 24 covers the metal liner layer 23 on the top surface of the low-k intermetal dielectric layer 18 as well as the side walls and floor of the trench 20. Optionally, a seed layer etchback (not shown) may be performed to reduce metal overhang at the top corners of the trench 20.

An electroplating process is then performed on the wafer to cause the remaining open portion of the trench 20 to be filled with metal 26 (FIG. 1G). Electroplated metal is also produced above the top of the wafer. Chemical mechanical polishing (CMP) is then performed to remove the excess and unwanted portions of the diffusion barrier layer 22, the metal seed layer 24 and the electroplated metal 26 which are located outside of the trench (FIG. 1H). The polishing operation further provides a flat top surface for the wafer that is ready for further integrated circuit processing. As part of that further processing, a dielectric cap layer 28 may be deposited on the flat top surface to protect the low-k intermetal dielectric layer and the metal layers and materials of the formed metal lines and interconnects (FIG. 1I).

The processes of FIGS. 1B-1I may then be repeated, as needed, to form additional metallization layers for the integrated circuit device. In this context, it will be understood that the underlying electrical contact member 16 could thus comprise the metal filled trench of an underlying metallization layer and the dielectric cap layer 28 could thus comprise one of the layers within the low-k intermetal dielectric layer 18.

The metal selected for the metal seed layer 24 and the electroplated metal 26 is typically copper. It will, of course, be understood that other materials could instead be chosen.

It is known in the art to add a dopant material to the copper sputtering target used in the deposition of the metal seed layer 24 (i.e., the sputtering target is formed of copper alloyed with another material). For example, the dopant may comprise manganese (Mn) or aluminum (Al). The added dopant material will typically be substantially uniformly distributed throughout the deposited copper seed layer 24. During the high temperature process used to form the dielectric cap layer 28, as well as during further other thermal cycles and processing operations associated with completing fabrication of the integrated circuit (such as with the addition of further metallization layers), those skilled in the art understand that the added dopant species may migrate from the copper seed layer 24 and diffuse through the electroplated copper metal 26 fill to form a self-aligned metal cap located at the interface 30 between the dielectric cap layer 28 and the electroplated copper metal 26 which fills the trench 20.

The diffusion barrier layer 22, metal liner layer 23 and metal seed layer 24 are typically formed using a plasma vapor deposition (PVD) process in a manner well known to those skilled in the art. Because PVD is essentially a line of sight type deposition process, the transfer of metal from the sputter target to locations along the side walls of the trench 20 can be blocked. For example, blocking may occur at protrusions formed on the side walls of the trench 20 by hard mask undercuts, reentrant gaps and rough side wall structures, and the shadowed areas will not receive a deposition. As a result, poor copper gap filling may occur due to a broken liner or seed layer or as a result of marginal seed layer coverage.

There has been some experimentation with the use of chemical vapor deposition (CVD) or atomic layer deposition (ALD) techniques known to those skilled in the art to deposit the metal liner layer 23. Such a liner layer has been shown to be somewhat effective in enhancing copper growth at shadowed locations within the trench 20.

It is desirable for a high percentage of the added dopant species to migrate from the seed layer 24 to the interface 30 between the dielectric cap layer 28 and the electroplated metal 26 which fills the trench 20 because this interface tends to be the initiation area of copper electromigration which can lead to circuit failure. The presence of a broken liner or seed layer or marginal seed layer coverage may adversely affect dopant species migration from the copper seed layer 24 towards the interface 30. Still further, the CVD or ALD processes used for depositing the metal liner layer produce a metal liner layer which includes impurities such as carbon and/or oxygen. These impurity species negatively affect the migration behavior of the doped species from the copper seed layer 24 towards the interface 30. Trapped and/or unsuccessfully migrated dopant species can significantly affect subsequent copper grain growth and produce an unacceptable increase in copper line resistance. In addition, if the metal liner layer 23 is in direct contact with the electroplated metal 26, for example due to a break in the seed layer 24, metal species of the metal liner layer 23 may diffuse into the bulk of the electroplated metal 26 and cause reliability problems.

As copper interconnect structures move towards finer geometries, there would be an advantage to having a diffusion barrier and liner which supports sufficient seed metal coverage on trench side walls, especially at hard mask undercuts and other critical locations. This would obviate concerns with breaks in seed layer coverage.

### SUMMARY

In an embodiment, a process comprises: opening a trench in a dielectric layer; lining the trench with a first diffusion barrier layer; lining the trench with a first conformal metal liner layer; lining the trench with a second diffusion barrier layer; lining the trench with a metal seed layer; and filling the trench with a metal fill.

In an embodiment, a process comprises: opening a trench in a dielectric layer; lining the trench with a sandwiched diffusion barrier and metal liner structure; lining the trench with a metal seed layer; and filling the trench with a metal fill; wherein the sandwiched diffusion barrier and metal liner structure comprises a conformal metal liner layer sandwiched between a first diffusion barrier layer and a second diffusion barrier layer.

In an embodiment, an apparatus comprises: a trench formed in a dielectric layer; a first diffusion barrier layer lining the trench; a first conformal metal liner layer lining the trench; a second diffusion barrier layer lining the trench; a metal seed layer lining the trench; and a metal fill that fills the trench.

In an embodiment, an apparatus comprises: a dielectric layer including a trench; a sandwiched diffusion barrier and metal liner structure lining the trench; a metal seed layer over the sandwiched diffusion barrier and metal liner structure; and a metal fill filling the trench; wherein the sandwiched diffusion barrier and metal liner structure comprises a conformal metal liner layer sandwiched between a first diffusion barrier layer and a second diffusion barrier layer.

### BRIEF DESCRIPTION OF THE DRAWINGS

For a better understanding of the embodiments, reference will now be made by way of example only to the accompanying figures in which:

FIGS. 1A to 1I illustrate process steps for forming a metal interconnect structure of an integrated circuit in accordance with the prior art;

FIGS. 2A to 2K illustrate process steps for forming a metal interconnect structure of an integrated circuit; and

FIG. 3 is a graph illustrating doping concentration of the metal seed layer as a function of trench depth.

### DETAILED DESCRIPTION OF THE DRAWINGS

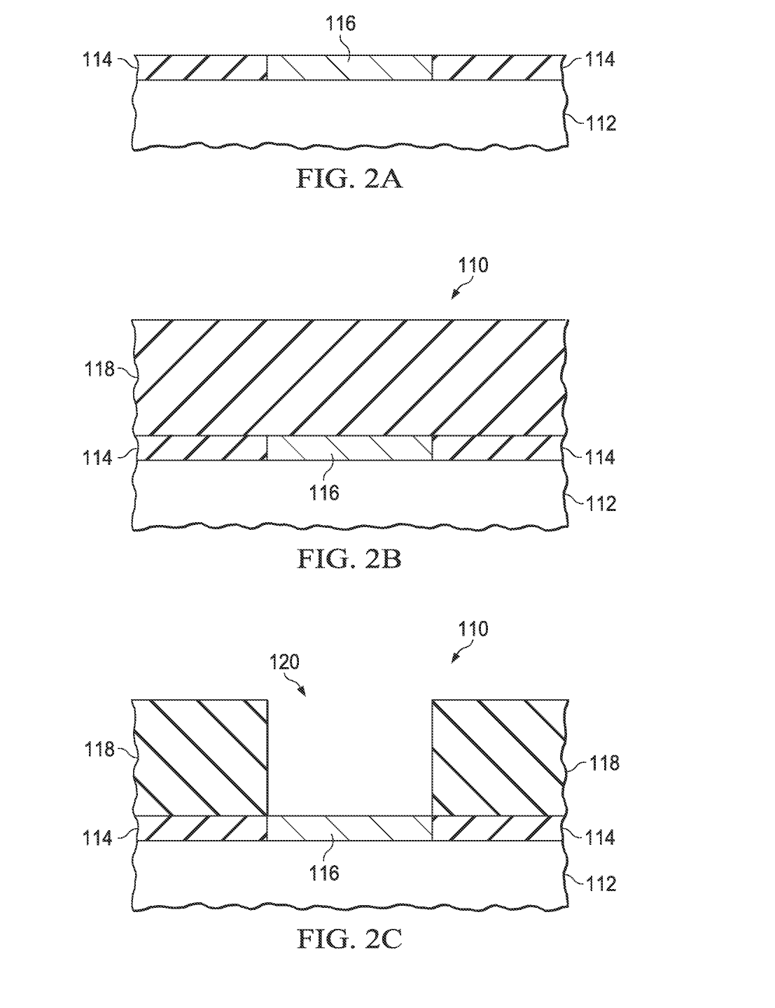

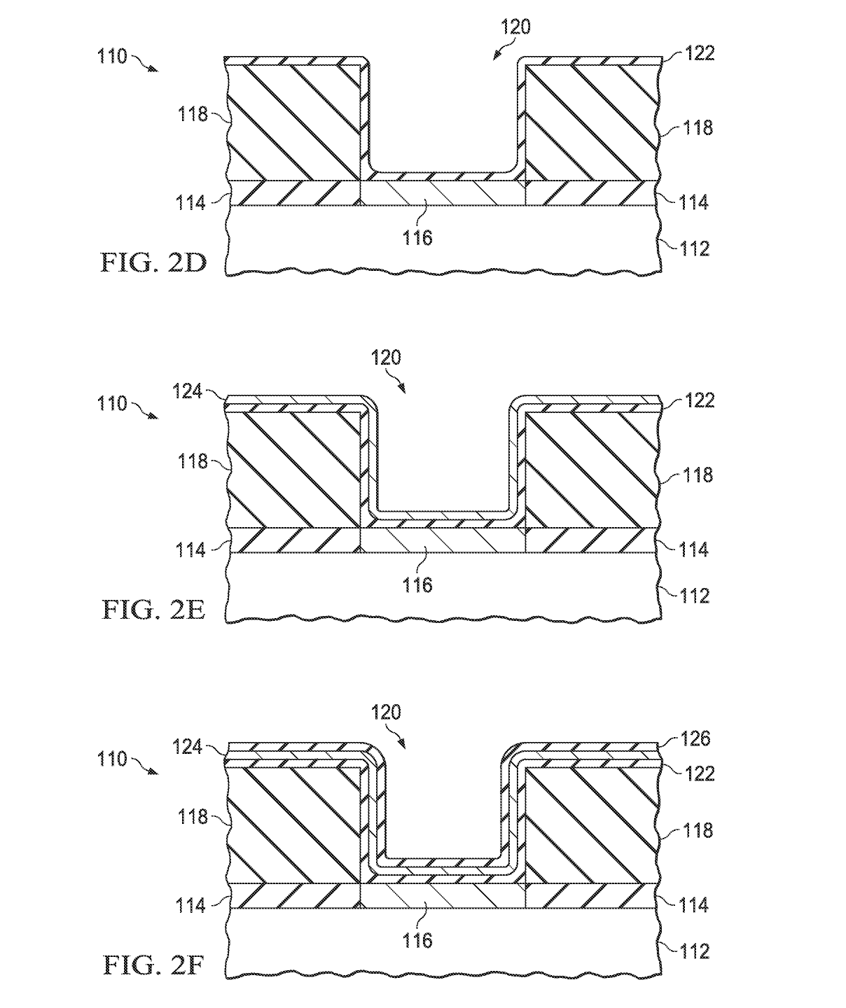

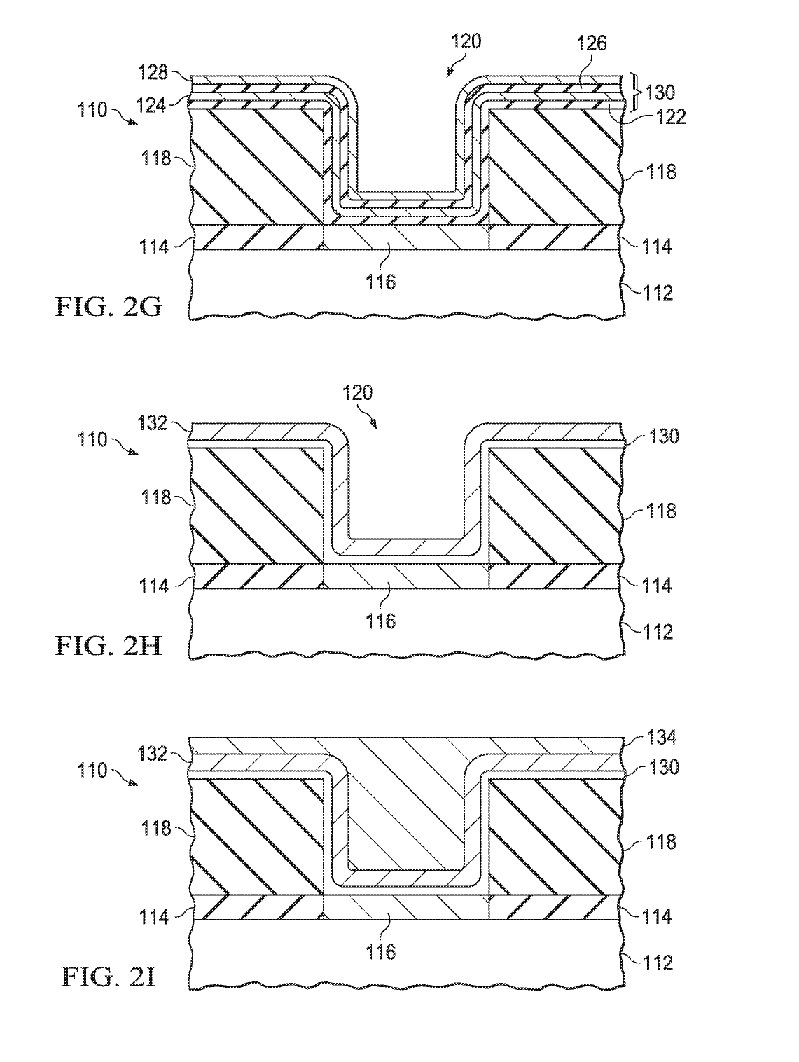

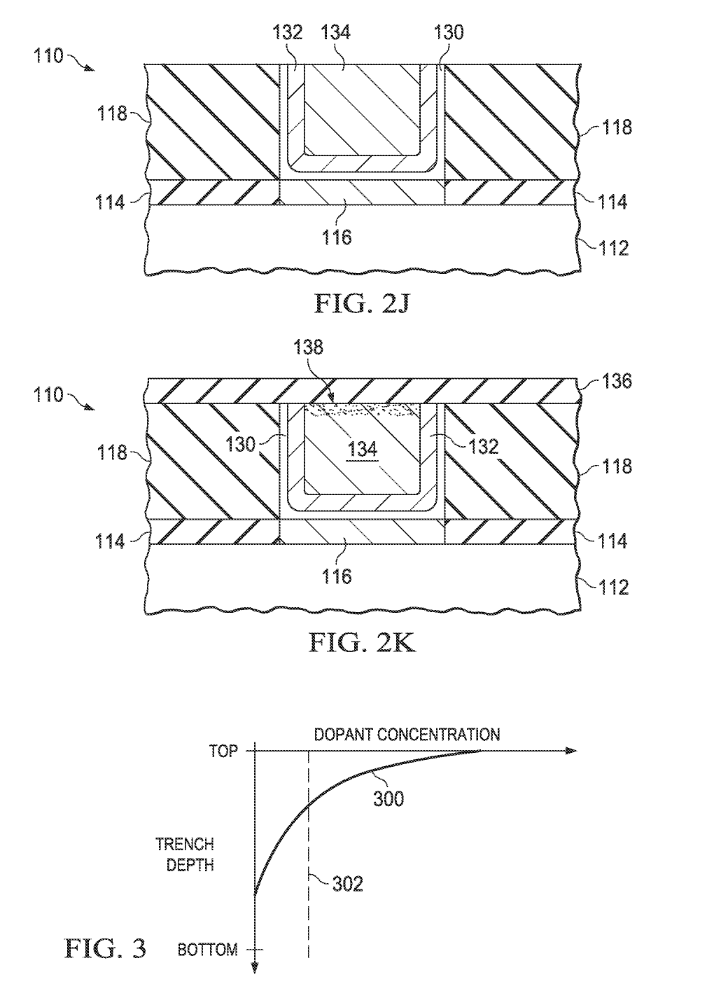

Reference is now made to FIGS. 2A-2K (not drawn to scale) which illustrate process steps for forming a metal interconnect structure of an integrated circuit. As shown in FIG. 2A, a wafer 110 is formed which comprises a semiconductor substrate 112 including integrated circuit devices formed in and/or on the substrate (not shown), a pre-metal dielectric (PMD) layer 114 overlying the substrate, and a plurality of electrical contact members 116, such as tungsten plugs or the like, extending through the PMD layer to reach the integrated circuit devices. The pre-metal dielectric (PMD) layer 114 is planarized using, for example, chemical mechanical polishing (CMP) to provide a flat surface for supporting metallization layers of the integrated circuit device. Next, a low-k intermetal dielectric layer 118 is provided over the PMD layer 114 (FIG. 2B), the dielectric layer 118 for example being formed of a multilayer structure including a low-k layer and one or mask layers (for example including a TEOS hard mask and titanium nitride hard mask). This low-k intermetal dielectric layer 118 is also planarized. A trench 120 is then formed extending into and perhaps through the multiple layers of the low-k intermetal dielectric layer 118 (FIG. 2C). The trench 120 is provided at a location where an interconnect structure is to be located, for example exposing a top surface of the underlying electrical contact member 116.

A blanket formation of a diffusion barrier layer 122 is then made (FIG. 2D). This diffusion barrier layer 122 serves to block the migration of subsequently deposited metal atoms for the interconnect structure into the low-k intermetal dielectric layer, as well as block the diffusion in the opposite direction of contaminants from the low-k intermetal dielectric layer to the interconnect structure. The diffusion barrier layer 122 is typically made of tantalum nitride.

Next, a chemical vapor deposition (CVD) or atomic layer deposition (ALD) process is used to conformally deposit a first metal liner layer 124. This first metal liner layer 124 covers the diffusion barrier layer 122 on the top surface of the low-k intermetal dielectric layer 118 as well as the side walls and floor of the trench 120. Thus, there is coverage provided for all exposed areas of the multi-layer low-k intermetal dielectric layer 118, including reentrant gaps, rough sidewalls, liner breaks and hard mask undercut areas where there may not exist a continuous coverage provided by the diffusion barrier layer 122. The first metal liner layer 124 is typically made of cobalt or ruthenium.

As an optional step, an etchback may be performed to remove portions of the conformally deposited first metal liner layer 124 which are located at or near the floor of the trench. As this step is optional, the figures do not explicitly illustrate the effects of the removal which could effectuate a partial or complete removal or redistribution with respect to the lower portions of the first metal liner layer 124.

A blanket formation of a second (additional) diffusion barrier layer 126 is then made (FIG. 2F). This diffusion barrier layer 126 further serves to block the migration of subsequently deposited metal atoms for the interconnect structure into the low-k intermetal dielectric layer, as well as block the diffusion in the opposite direction of contaminants from the low-k intermetal dielectric layer to the interconnect structure. The diffusion barrier layer 126 is typically made of tantalum nitride.

Next, a second (additional) metal liner layer 128 is deposited over the additional diffusion barrier layer 126 (FIG. 2G). The second metal liner layer 128 functions as an adhesion layer that assists in increasing the adhesion of subsequently deposited layers. The second metal liner layer 128 is typically made of tantalum.

The layers 122, 124, 126 and 128 considered together form a sandwiched diffusion barrier and metal liner 130. For ease of illustration only, the multiple layers (122, 124, 126 and 128) of the sandwiched diffusion barrier and metal liner 130 will be illustrated in the following figures collapsed together as a single layer.

A metal seed layer 132 is then formed on the wafer (FIG. 2H) using any suitable deposition process such as sputtering over the sandwiched diffusion barrier and metal liner 130. This seed layer 132 covers the sandwiched diffusion barrier and metal liner 130 on the top surface of the low-k intermetal dielectric layer 118 as well as the side walls and floor of the trench 120. Optionally, a seed layer etchback (not shown) may be performed to reduce metal overhang at the top corners of the trench 120.

The metal seed layer 132 preferably comprises copper. In an embodiment, the metal seed layer 132 is either un-doped or substantially uniformly doped (for example, with manganese (Mn) or aluminum (Al)). In another embodiment, the metal seed layer 132 is non-uniformly doped and exhibits a vertical doping gradient (i.e., the concentration of dopant species in the metal seed layer 132 varies by decreasing as a function of depth).

Reference is now made to FIG. 3 which shows a graph illustrating the doping concentration of the metal seed layer 132 as a function of trench depth. Reference 300 illustrates a vertical doping gradient where a higher concentration of dopant species is present on the top surface of the low-k intermetal dielectric layer 118 and at and near the top of the trench 120, while there is little to no dopant present in the metal seed layer 132 at or near the bottom of the trench 120. Reference 302 on the other hand illustrates a substantially uniform doping concentration as a function of trench depth. As an exemplary implementation, the relatively uniform doping concentration 302 may be at or about 0.5% and the gradient for the non-uniform doping concentration 300 may extend from about 0% at the bottom of the trench to about 5%-10% at the top of the trench. Trench depth may, for example, be about 100-200 nm and more particularly be about 150 nm.

The formation of a metal seed layer 132 having a non-uniformly doped configuration is described in detail in co-pending U.S. application for patent Ser. No. 13/682,162, filed Nov. 20, 2012, entitled “Copper Seed Layer For An Interconnect Structure Having A Doping Concentration Level Gradient” (Attorney Docket No. 328940-1412), the disclosure of which is incorporated herein by reference.

Reference is once again made to FIGS. 2A-2K. An electroplating process is then performed on the wafer to fill the remaining open portion of the trench 120 with metal 134 (FIG. 2I). Electroplated metal is also produced above the top of the wafer. Chemical mechanical polishing (CMP) is then performed to remove the excess and unwanted portions of the sandwiched diffusion barrier and metal liner 130, the metal seed layer 132 and the electroplated metal 134 that are located outside of the trench (FIG. 2J). The polishing operation further provides a flat top surface for the wafer that is ready for further integrated circuit processing. As part of that further processing, a dielectric cap layer 136 may be deposited on the flat top surface to protect the low-k intermetal dielectric layer and the metal layers and materials of the formed metal lines and interconnects (FIG. 2K).

The processes of FIGS. 2B-2K may then be repeated, as needed, to form additional metallization layers for the integrated circuit device. In this context, it will be understood that the underlying electrical contact member 116 could thus comprise the filled trench of an underlying metallization layer and the dielectric cap layer 136 could thus comprise one of the layers within the low-k intermetal dielectric layer 118.

The performance of the high temperature process used to form the dielectric cap layer 136, as well as the performance of other thermal cycles and processing operations associated with completing fabrication of the integrated circuit (such as with the addition of further metallization layers), causes a migration of the dopant species from the doped seed layer 132 towards the interface 138 between the dielectric cap layer 136 and the electroplated metal 134 which fills the trench 120. This migration forms a self-aligned metal cap 132 (shown by the stippling at the interface 138 in FIG. 2K).

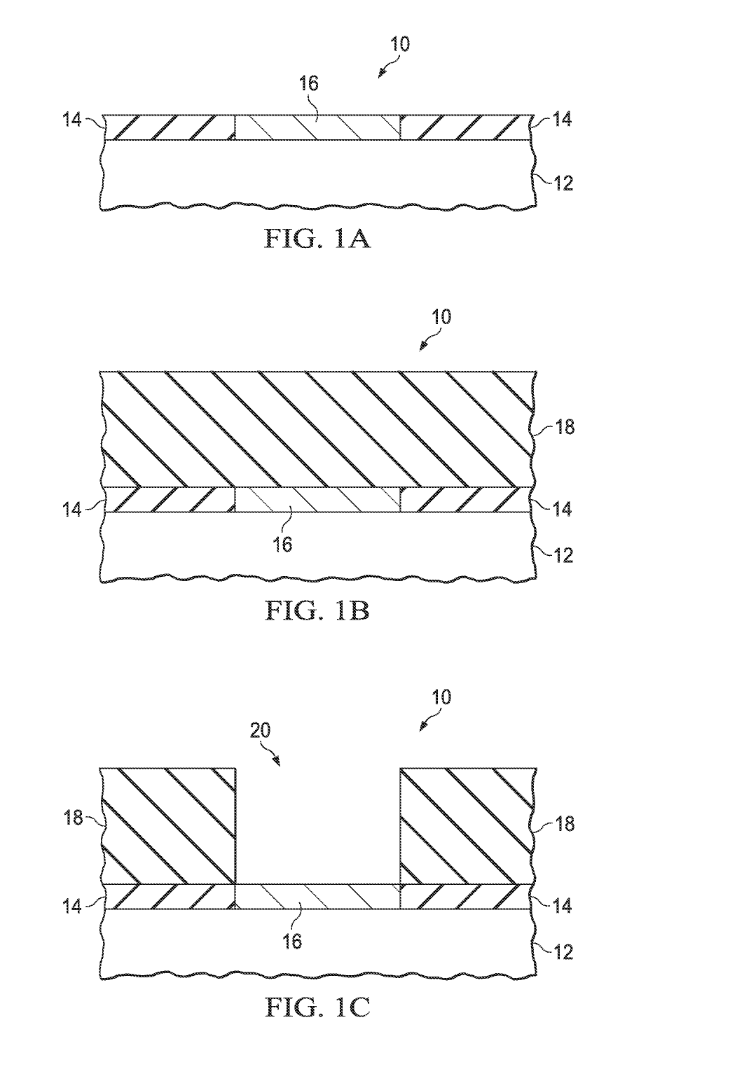

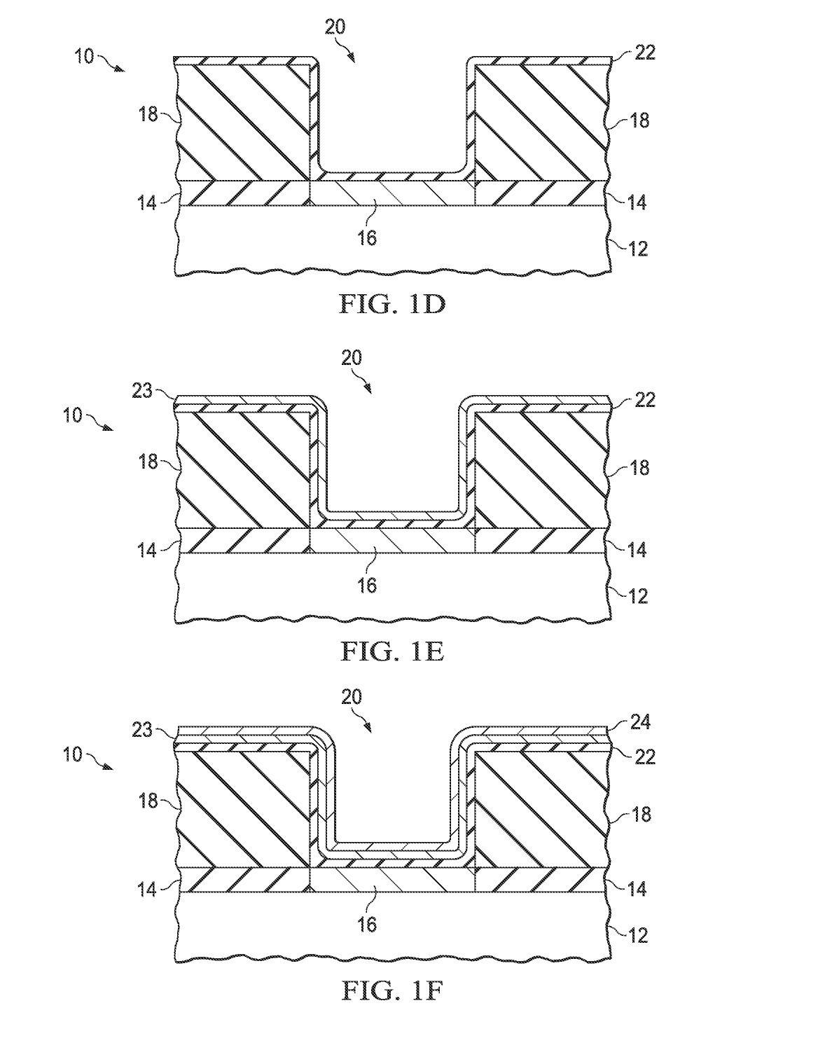

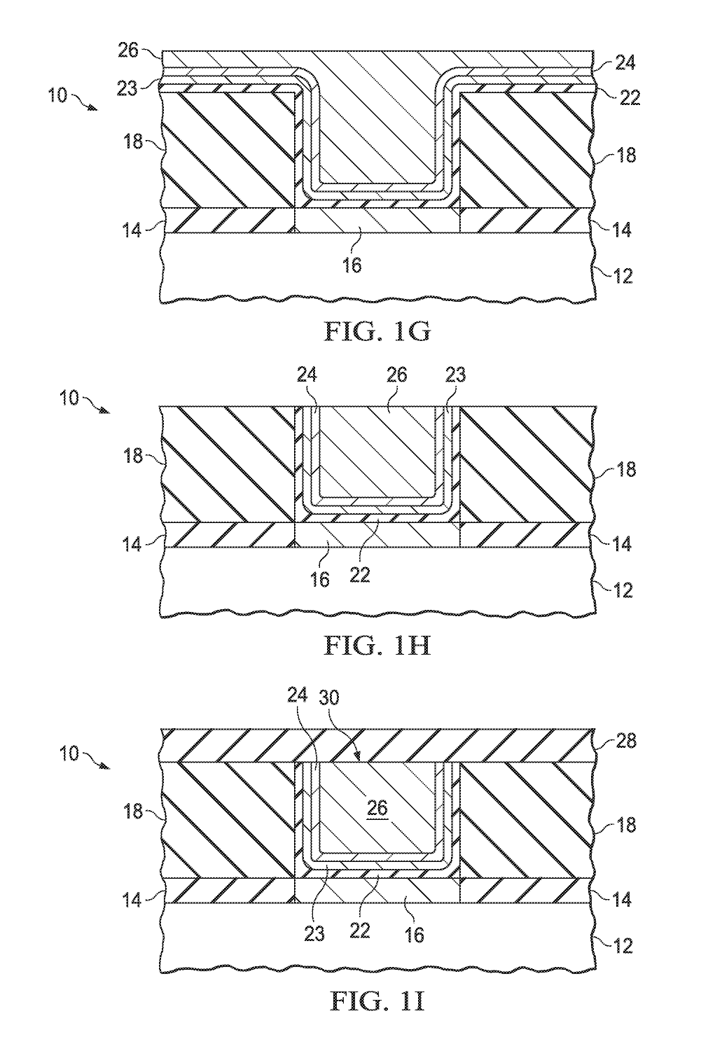

In locations such as hardmask undercuts where there is a potential for a liner discontinuity to exist, the conformally deposited (for example, by chemical vapor deposition (CVP) or atomic layer deposition (ALD)) first metal liner layer 124 of the sandwiched diffusion barrier and liner 130 serves to prevent occurrences of breaks in the subsequently deposited metal seed layer 132. Additionally, even if metal seed layer 132 coverage is marginal at a critical location, the conformally deposited first metal liner layer 124 of the sandwiched diffusion barrier and liner 130 supports current flow during the electroplating process which fills the remaining open portion of the trench 120 with metal 134. By forming the sandwiched diffusion barrier and liner 130 with the conformally deposited first metal liner layer 124 positioned between the diffusion barrier layers 122 and 126 of the sandwiched diffusion barrier and metal liner 130, the diffusion barrier layers 122 and 126 function to ensure that the conformally deposited first metal liner layer 124 does not diffuse into the low-k intermetal dielectric layer 118 or the electroplated fill metal 134. Lastly, the additional diffusion barrier layer 126 separates the metal seed layer 132 from the conformally deposited first metal liner layer 124 and thus supports efficient migration of dopant species from the metal seed layer 132 to the interface 138 between the dielectric cap layer 136 and the electroplated metal 134 which fills the trench 120. As a result, an integrated circuit including the structure shown in FIG. 2K possesses decreased copper line resistance, better formation of a barrier or adhesion layer at the interface, and better reliability (lower circuit failure rate) relative to the embodiment shown in FIG. 1I.

Although illustrated in connection with a damascene process, it will be understood that the method described herein for forming a sandwiched diffusion barrier and metal liner 130 is equally applicable to the dual damascene process as well as to other processes known in the art which are used to fill trench-like structures in integrated circuit devices with a metal material.

The metal selected for the metal seed layer 132 and the electroplated metal 134 is typically copper. The dopant species may comprise manganese (Mn) or aluminum (Al).

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

What is claimed is:

1. A process, comprising:
opening a trench in a dielectric layer;
lining the trench with a first diffusion barrier layer;
lining the trench with a first conformal metal liner layer;
lining the trench with a second diffusion barrier layer;
lining the trench with a metal seed layer; and
filling the trench with a metal fill.

2. The process of claim 1, wherein lining the trench with the first conformal metal liner layer comprises performing chemical vapor deposition to deposit the first conformal metal liner layer.

3. The process of claim 1, wherein lining the trench with the first conformal metal liner layer comprises performing atomic layer deposition to deposit the first conformal metal liner layer.

4. The process of claim 1, wherein the trench is associated with an interconnect structure of an integrated circuit.

5. The process of claim 1, wherein lining the trench with the metal seed layer comprises depositing a doped metal seed layer.

6. The process of claim 5, wherein the doped metal seed layer is non-uniformly doped and exhibits a vertical doping gradient varying as a function of trench depth.

7. The process of claim 5, further comprising depositing a dielectric cap layer over the metal filled trench.

8. The process of claim 7, further comprising migrating dopant from the non-uniformly doped metal seed layer to an interface between the metal filled trench and the dielectric cap layer to form a self-aligned metal cap.

9. The process of claim 5, wherein a dopant material of the metal seed layer is selected from the group consisting of manganese and aluminum.

10. The process of claim 1, further comprising lining the trench with a second metal liner layer before lining the trench with the metal seed layer.

11. A process, comprising:
opening a trench in a dielectric layer;
lining the trench with a sandwiched diffusion barrier and metal liner structure;
lining the trench with a metal seed layer; and
filling the trench with a metal fill;
wherein the sandwiched diffusion barrier and metal liner structure comprises a conformal metal liner layer sandwiched between a first diffusion barrier layer and a second diffusion barrier layer.

12. The process of claim 11, wherein lining the trench with the sandwiched diffusion barrier and metal liner structure comprises:
lining the trench with the first diffusion barrier layer;
lining the trench with the conformal metal liner layer; and
lining the trench with the second diffusion barrier layer.

13. The process of claim 12, wherein lining the trench with the sandwiched diffusion barrier and metal liner structure further comprises lining the trench with a second metal liner layer.

14. The process of claim 12, wherein lining the trench with the conformal metal liner layer comprises performing chemical vapor deposition to deposit the conformal metal liner layer.

15. The process of claim 12, wherein lining the trench with the conformal metal liner layer comprises performing atomic layer deposition to deposit the conformal metal liner layer.

16. The process of claim 12, wherein lining the trench with the metal seed layer comprises depositing a doped metal seed layer.

17. The process of claim 16, further comprising depositing a dielectric cap layer over the metal filled trench.

18. The process of claim 17, further comprising migrating dopant from the non-uniformly doped metal seed layer to an interface between the metal filled trench and the dielectric cap layer to form a self-aligned metal cap.

19. An apparatus, comprising:
a trench formed in a dielectric layer;
a first diffusion barrier layer lining the trench;
a first conformal metal liner layer lining the trench;
a second diffusion barrier layer lining the trench;
a metal seed layer lining the trench; and
a metal fill that fills the trench.

20. The apparatus of claim 19, further comprising a second metal liner layer lining the trench between the second diffusion barrier layer and the metal seed layer.

21. The apparatus of claim 19, wherein the metal filled trench defines an interconnect structure of an integrated circuit.

22. The apparatus of claim 19, further comprising a dielectric cap layer formed over the metal filled trench.

23. The apparatus of claim 22, further comprising a self-aligned metal cap formed at an interface between the metal filled trench and the dielectric cap layer.

24. An apparatus, comprising:
a dielectric layer including a trench;
a sandwiched diffusion barrier and metal liner structure lining the trench;
a metal seed layer over the sandwiched diffusion barrier and metal liner structure; and
a metal fill filling the trench;
wherein the sandwiched diffusion barrier and metal liner structure comprises a conformal metal liner layer sandwiched between a first diffusion barrier layer and a second diffusion barrier layer.

25. The apparatus of claim 24, wherein the sandwiched diffusion barrier and metal liner structure further comprises a second metal liner layer between the second diffusion barrier layer and the metal seed layer.
